(19) United States
(12) Patent Application Publication
(10) Pub. No.: US 2006/0182530 A1
(43) Pub. Date: Aug. 17, 2006

(54) WAFER LOADLOCK CHAMBER AND WAFER HOLDER

(76) Inventor: Min-Hsu Wang, Tainan County (TW)

Correspondence Address: NORTH AMERICA INTELLECTUAL PROPERTY CORPORATION, P.O. BOX 506, MERRIFIELD, VA, 22116, US

(21) Appl. No.: 10/905,462

(22) Filed: Jan. 5, 2005

(51) Int. Cl. H01L 21/677

(52) U.S. Cl. 414/217

(57) ABSTRACT

A wafer loadlock chamber includes a loadlock housing having at least a loading port, at least a loading door deposited on the outside of the loadlock housing, and at least a wafer holder deposited in the inside of the loadlock housing for loading a wafer. In addition, the wafer holder has at least a wafer shelf and a plurality of locators mounted on the wafer shelf. When the wafer is loaded on the wafer shelf, the bottom surface of the wafer only contacts the locators.

### BACKGROUND OF INVENTION

1. Field of the Invention

The invention relates to a wafer loadlock chamber and a wafer holder, and more particularly, to the wafer loadlock chamber and the wafer holder with reduced thermal stress.

2. Description of the Prior Art

Very large scale integration (VLSI) fabrication is based on a semiconductor wafer and is implemented with tens or even hundreds of semiconductor processes to form a plurality of dies having devices and connections therein. These dies are then segmented and packaged to form a plurality of chips for different applications. During the semiconductor processes, there are very high temperatures in some processes. To allow wafers to cool down quickly and then proceed with the next process, the wafer loadlock chamber is built as a buffer station for a cooling wafer.

Please refer to FIG. 1, which is a schematic diagram of wafer holder according to prior art. The wafer holder 10 that is deposited in a wafer loadlock chamber (not shown) comprises a wafer shelf 12 having two sheets 12a, 12b for loading the wafer. Usually, a plurality of wafer holders 10 are stacked in the loadlock chamber, and each wafer holder 10 is for loading an individual wafer. During wafer processing, there are very high temperatures in some processes so that a buffer station for a wafer is built for loading a heated wafer onto the wafer shelf 12 of the wafer loadlock chamber and waiting for the wafer to cool before proceeding to the next process. For example, the wafer usually is heated to 200 degrees Celsius in a strip process, so the wafer cannot be directly processed in next process. Therefore, the heated wafer is delivered to the wafer loadlock chamber and loaded onto the wafer shelf 12 until the wafer cools sufficiently.

Please refer to FIG. 2, which is a vertical view of a wafer 14 loaded on the wafer holder 10 shown in FIG. 1. When the wafer 14 is loaded onto the wafer shelf 12, two sides of the wafer 14 have a large contact area with the sheets 12a, 12b. According to heat conduction principles, the two contacting sides of the wafer 14 cool quicker than the center of the wafer 14. Thus, there are temperature differences between the sides and center of the wafer 14 so that the center of the wafer 14 breaks (as shown by an arrow) due to thermal stress influences and the broken wafer scrapes other wafers in the wafer loadlock chamber.

As described, the wafer holder 10 and the wafer 14 belong to “face” contact methods according to prior art. Thus, the sides of the wafer 14 contacting the wafer shelf 12 cool quicker than the portion of the wafer 14 detached from the wafer shelf 12 due to thermal stress influences. Therefore, the manufacturing process for semiconductor still needs improvement to enhance the reliability and yield of wafer production.

### SUMMARY OF INVENTION

It is therefore a primary objective of the claimed invention to provide a wafer loadlock chamber and wafer holder to solve the above-mentioned problem.

According to the claimed invention, a wafer loadlock chamber includes a loadlock housing having at least a loading port, at least a loading door deposited on the outside of the loadlock housing, and at least a wafer holder deposited inside of the loadlock housing for loading a wafer. In addition, the wafer holder includes at least a wafer shelf and a plurality of locators mounted on the top of the wafer shelf. Finally, when the wafer is loaded on the wafer shelf, the bottom surface of the wafer only contacts the locators.

It is an advantage of the claimed invention that the wafer only contacts the locators of the wafer shelf. The wafer and the wafer holder belong to “point” contact ideology, so the cooling method is a radiative cooling that can effectively avoid the temperature differences between the center and sides of the wafer, enhance the reliability and yield of wafer production, and reduce the cost.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of a wafer holder according to prior art.

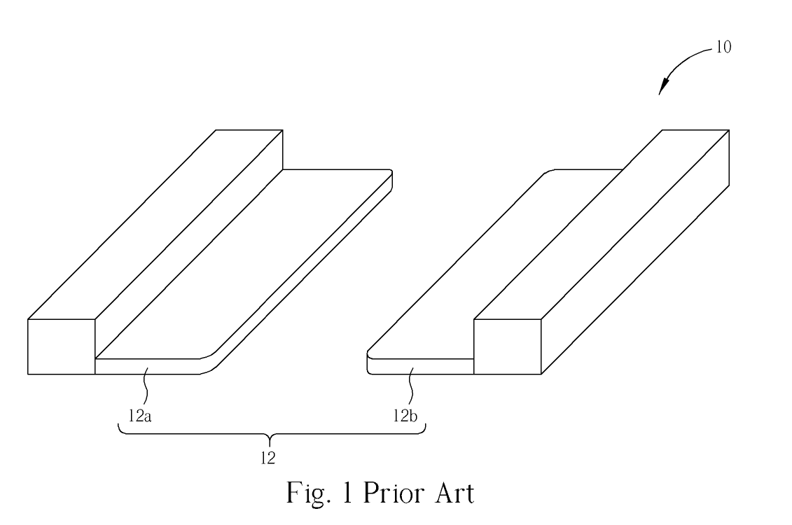

FIG. 2 is a vertical view of a wafer loaded on the wafer holder shown in FIG. 1.

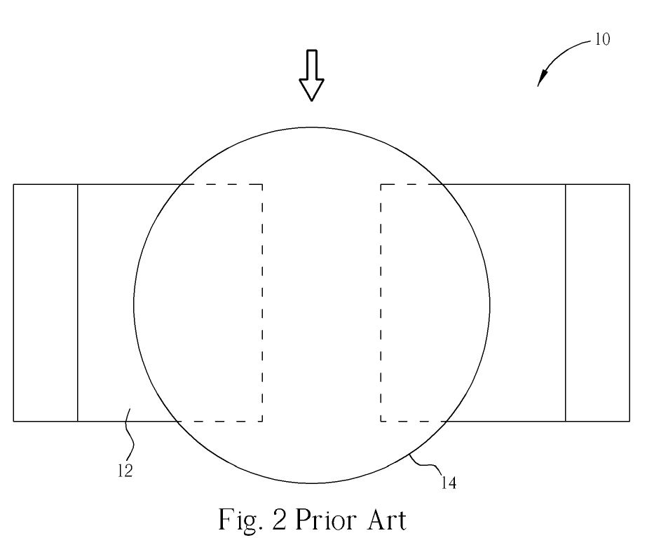

FIG. 3 is a schematic diagram of a wafer loadlock chamber and a wafer holder according to the present invention.

FIG. 4 is a magnifying schematic diagram of the wafer holder shown in FIG. 3.

FIG. 5 is a magnifying schematic diagram of the locators shown in FIG. 4.

FIG. 6 is a schematic diagram of a wafer holder according to another embodiment of the present invention.

### DETAILED DESCRIPTION

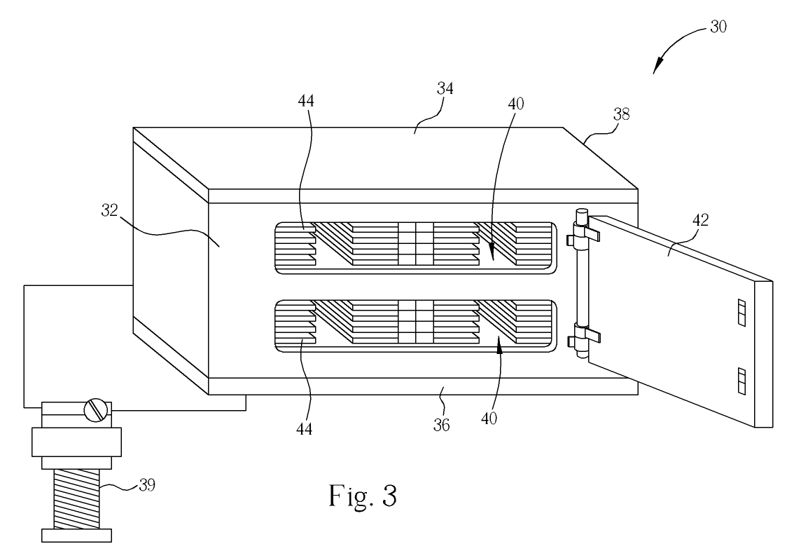

Please refer to FIG. 3, which is a schematic diagram of a wafer loadlock chamber and a wafer holder according to the present invention. As shown in FIG. 3, the present invention provides a loadlock chamber 30 that includes a loadlock housing 38 having at least a sidewall 32, a lid 34, and a bottom 36. A loading port 40 is deposited in the sidewall 32 of the loadlock housing 38, at least a loading door 42 is deposited on the outside of the sidewall 32 of the loadlock housing 38, and a plurality of wafer holders 44 are deposited in the loadlock housing 38. The loading port 40 is a door or window for allowing wafers to be moved into or out of the wafer holders 44, and the loadlock door 42 is a valve for isolation from the outside environment. The wafer holders 44 are stacked in the loadlock housing 38, and there is an interval for loading the wafer between a wafer shelf and another wafer shelf in the wafer holders 44.

In addition, the wafer loadlock chamber 30 further includes a vacuum system 39. When the wafers are loaded on the wafer holders 44 and the loadlock door 42 is closed, air in the wafer loadlock chamber 30 is drawn out by the vacuum system, allowing the wafers cool in the vacuum. On the other hand, the loadlock chamber 30 can include a cooling system (not shown) deposited in the loadlock housing 38 with the cooling system having a plurality of cooling aqueducts for making the wafers on the wafer holders 44 cool quickly.

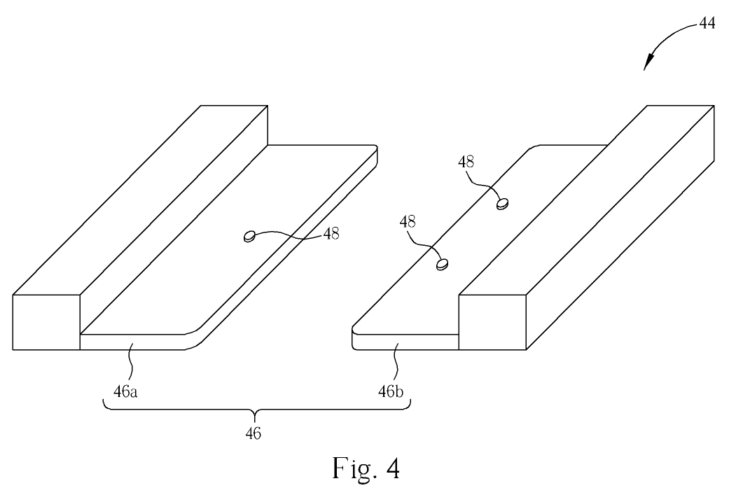

FIG. 4 is a magnifying schematic diagram of the wafer holder shown in FIG. 3. The wafer holder 44 includes at least a wafer shelf 46 and a plurality of locators 48. The wafer shelf 46 has two detached but level sheets 46a, 46b for loading wafer. In addition, the wafer holder 44 comprises at least three locators 48, and the locators 48 are upwardly directed salient points and are individually mounted on the sheets 46a, 46b of the wafer shelf 46. As shown in FIG. 4, when the locators 48 are mounted on the wafer shelf 46, the locators 48 are prominent on the wafer shelf 46. In one embodiment of the present invention, the locators 48 have a flat top face for loading the wafer.

When the wafer is loaded on the wafer shelf 46 of the wafer holder 44, the center of the wafer is located on the figure formed by the locators 48 (such as a triangle formed by 3 locators as a non-limiting example), and the bottom of the wafer is only in contact with the top faces of the locators 48. Furthermore, the contact area of the wafer and the locators 48 is less than 30 percent of the wafer area. Better results may be obtained if the contact areas are reduced to 20-30 percent, 10-20 percent, or even 1-10 percent.

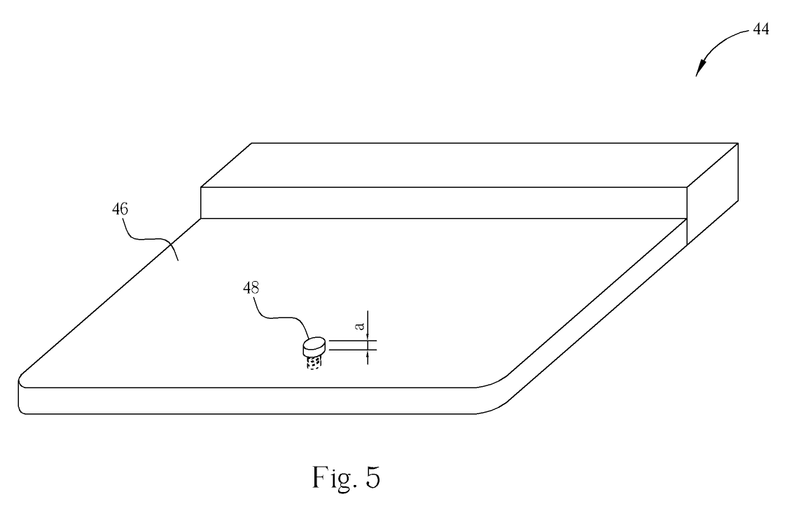

FIG. 5 is a magnifying schematic diagram of the wafer holder shown in FIG. 3. The wafer shelf 46 may have a hole made by drilling and lathing and then the locators 48 are mounted on the wafer shelf 46, or the wafer shelf 46 and the locators 48 may be fabricated together. The locators 48 are a thermostable material similar to the wafer shelf 46, such as aluminum, Teflon (polytetrafluoroethylene), or the combination of the aluminum and Teflon. In addition, the height of the locators 48, meaning the distance between the wafer contacting faces of the locators 48 and the sheets 46a, 46b, is less than 7 mm so that the wafer is stably loaded on the wafer shelf 46.

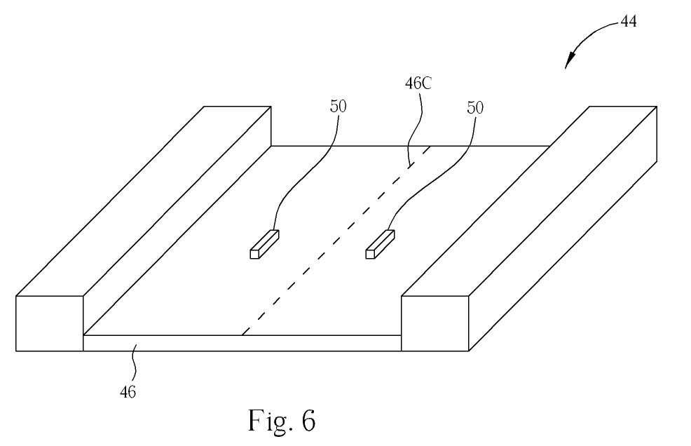

Please refer to FIG. 6, which is a schematic diagram of a wafer holder according to another embodiment of the present invention. For convenient illustration in FIG. 6, similar components retain the same label numbers that were used in FIG. 4. The wafer holder 44 includes a wafer shelf 46 having two sheets. The wafer holder 44 further includes a plurality of locators 50 mounted on the wafer shelf 46, and the locators 50 are upwardly raised strips located separately on two sides of the centerline 46c of the wafer shelf 46. When the wafer is loaded on the wafer holder 44, the bottom area of the wafer only contacts the locaters 50 individually located on two sides of the centerline 46c. The fabrication of the locators 50 is as same as the locaters 48 shown in FIG. 4. The wafer shelf 46 and the locators 48 may be fabricated together, or a hole in the wafer shelf 46 may be dug by drilling and lathing and then the locators 50 are mounted on the wafer shelf 46. The latter approach can directly modified by the equipment of the factory to improve the cooling efficiency without increasing the cost of changing the wafer shelf.

Generally, the wafer loadlock chamber 30 is a cooling chamber for a buffer station in the semiconductor process and for loading the heated wafer on the wafer holder 44. When the wafer temperature becomes room temperature, the wafer is processed in the next process. For example, the buffer station after a strip process on the semiconductor is for loading the heated wafer on the wafer holder 44 for cooling.

In summation, the wafer holder belongs to a “point” contact device according to the present invention, so the contact areas of the wafer and locators of the present invention are less than the contact areas in the prior art. On the other hand, the cooling rate of the center of the wafer is similar to the cooling rate of the edge of the wafer so that the effect of the thermal stress is avoided, the breaking and/or scraping of wafer is decreased, and wafer warpage is prevented. As a result, the wafer loadlock chamber and the wafer holder according to present invention not only enhance the reliability of wafer and the yield for production, but also reduce the cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer loadlock chamber comprising:
a loadlock housing having at least a loading port;
at least a loading door deposited on the outside of the loadlock housing; and
at least a wafer holder deposited in the inside of the loadlock housing for loading a wafer,
the wafer holder comprising:
at least a wafer shelf; and
a plurality of locators mounted on the wafer shelf;
wherein when the wafer is loaded on the wafer shelf, the bottom surface of the wafer only contacts the locators.

2. The wafer loadlock chamber of claim 1, wherein when the wafer is loaded on the wafer shelf, the contact area of the wafer and the locators is less than 30 percent of the area of the wafer.

3. The wafer loadlock chamber of claim 2, wherein the range of contact area of the wafer and the locators is 20-30 percent of the wafer area.

4. The wafer loadlock chamber of claim 2, wherein the range of contact area of the wafer and the locators is 10-20 percent of the wafer area.

5. The wafer loadlock chamber of claim 2, wherein the range of contact area of the wafer and the locators is 1-10 percent of the wafer area.

6. The wafer loadlock chamber of claim 1, wherein each locator is an upwardly raised strip.

7. The wafer loadlock chamber of claim 6, wherein the wafer holder comprises two locators, and when the wafer is loaded on the wafer shelf, the locators are individually mounted on the either side of a centerline of the wafer.

8. The wafer loadlock chamber of claim 1, wherein each locator is an upwardly directed salient point.

9. The wafer loadlock chamber of claim 1, wherein the wafer holder comprises at least three locators.

10. The wafer loadlock chamber of claim 1, wherein the wafer loadlock chamber comprises a plurality of the wafer holders.

11. The wafer loadlock chamber of claim 10, wherein the wafer holders are stacked in the loadlock chamber.

12. The wafer loadlock chamber of claim 11, wherein an interval exists between the wafer shelf and another wafer shelf in the wafer holders.

13. The wafer loadlock chamber of claim 1, wherein the wafer shelf comprises a plurality of detached but level sheets for loading the wafer.

14. The wafer loadlock chamber of claim 1, wherein the height of the locators is less than 7 mm.

15. The wafer loadlock chamber of claim 1, wherein the material of the locators is the same as the material of the wafer shelf.

16. The wafer loadlock chamber of claim 1, wherein the material of the locators is a thermostable material.

17. The wafer loadlock chamber of claim 16, wherein the material of the locators comprise aluminum, Teflon (polytetrafluoroethylene), or the combination of the aluminum and Teflon.

18. The wafer loadlock chamber of claim 1, wherein the wafer loadlock chamber is a cooling chamber.

19. The wafer loadlock chamber of claim 1, wherein the wafer loadlock chamber further comprises a vacuum system.

20. The wafer loadlock chamber of claim 1, wherein the wafer loadlock chamber is suitable as a buffer station after a strip process on a semiconductor and is for loading the wafer after finishing the strip process.

21. A wafer holder deposited in the wafer loadlock chamber for loading a wafer after a high temperature process, the wafer holder comprising:
a sheet wafer shelf; and
at least two locators mounted on the wafer shelf, when the wafer is loaded on the wafer holder, the wafer only contacts the locators, and the contact area of the wafer and the locators is less than 30 percent of the wafer area.

22. The wafer holder of claim 21, wherein the range of contact area of the wafer and the locators is 20-30 percent of the wafer area.

23. The wafer holder of claim 21, wherein the range of contact area of the wafer and the locators is 10-20 percent of the wafer area.

24. The wafer holder of claim 21, wherein the range of contact area of the wafer and the locators is 1-10 percent of the wafer area.

25. The wafer holder of claim 21, wherein each locator is an upwardly raised strip.

26. The wafer holder of claim 25, wherein the locators are individually mounted on either side of a centerline of the wafer.

27. The wafer holder of claim 21, wherein each locator is an upwardly directed salient point.

28. The wafer holder of claim 27, wherein the wafer holder comprises at least three locators.

29. The wafer holder of claim 28, wherein when the wafer is loaded on wafer holder, the center of the wafer is located on the figure formed by the locators.

30. The wafer holder of claim 21, wherein each locator comprises a flat top face, when the wafer is loaded on the wafer holder, the wafer only contacts the top face of each locator.

31. The wafer holder of claim 21, wherein the wafer shelf comprises two detached but level sheets for loading the wafer.

32. The wafer holder of claim 21, wherein the height of the locators is less than 7 mm.

33. The wafer holder of claim 21, wherein the material of the locator is the same as the material of the wafer shelf.

34. The wafer holder of claim 21, wherein the material of the locator is a thermostable material.

35. The wafer holder of claim 34, wherein the material of the locators comprises aluminum, Teflon (polytetrafluoroethylene), or the combination of the aluminum and Teflon.

36. The wafer holder of claim 21, wherein the wafer loadlock chamber is a cooling chamber.

37. The wafer holder of claim 21, wherein the wafer holder is suitable as a buffer station after a strip process on a semiconductor and the high temperature process is the strip process.
